(19) United States
(12) Patent Application Publication
(10) Pub. No.: US 2016/0163948 A1
(43) Pub. Date: Jun. 9, 2016

(54) Thermoelectric Device Fabrication Using Direct Bonding

(71) Applicant: GMZ Energy, Inc., Waltham, MA (US)

(72) Inventor: Xiaowei Wang, Chestnut Hill, MA (US)

(73) Assignee: GMZ Energy, Inc., Waltham, MA (US)

(21) Appl. No.: 14/206,199

(22) Filed: Mar. 12, 2014

Related U.S. Application Data
(60) Provisional application No. 61/783,333, filed on Mar. 14, 2013.

(51) Int. Cl. H01L 35/32; H01L 35/34

(52) U.S. Cl. CPC H01L 35/32; H01L 35/34

(57) ABSTRACT

Methods of fabricating a thermoelectric element include bonding at least one thermoelectric material leg to at least one of a header and an electrical connector using a direct bonding process. The direct bonding process may include liquid diffusion (e.g., brazing) or solid state diffusion bonding. The thermoelectric material leg may be directly bonded to the header or electrical connector without the use of a metal contact layer between the thermoelectric material leg and the header or electrical connector.

### RELATED APPLICATION

This application claims the benefit of priority to U.S. Provisional Application No. 61/783,333 filed on Mar. 14, 2013, the entire teachings of which are incorporated herein by reference.

### BACKGROUND

Devices for cooling and power generation based on thermoelectric effects are known in the art. Solid-state devices that employ the Seebeck effect or Peltier effect for power generation and heat pumping are known. For power generation, for example, a thermoelectric converter relies on the Seebeck effect to convert temperature differences into electricity. A thermoelectric generator (TEG) module includes a first (hot) side, a second (cold) side, and a plurality of thermoelectric converters disposed there between (e.g., pairs of p-type and n-type legs of thermoelectric material). Electrically conductive leads may provide appropriate electrical coupling within and/or between thermoelectric converters, and may be used to extract electrical energy generated by the converters.

### SUMMARY

Embodiments include a method of fabricating a thermoelectric element that includes bonding at least one thermoelectric material leg to at least one of a header and an electrical connector using a direct bonding process. In various embodiments, the direct bonding process may include a liquid state diffusion bonding process, such as brazing or soldering, or a solid state diffusion bonding process, which may be performed with or without a solid interface material. The at least one thermoelectric material leg may be directly bonded to the header or electrical connector without the use of a metal contact layer between the thermoelectric material leg and the header or electrical connector.

Further embodiments include a thermoelectric device that comprises a unicouple comprising an electrically conductive header and a p-type thermoelectric material leg and an n-type thermoelectric material leg with a direct bond at an interface between the thermoelectric material of each leg and the header.

Further embodiments include thermoelectric devices formed using a direct bonding process.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a schematic perspective view of a wafer of thermoelectric material that is diced to provide a plurality of thermoelectric elements.

FIG. 2 is a process flow diagram illustrating a method for fabricating thermoelectric legs.

FIG. 3 schematically illustrates a prior art method of fabricating a thermoelectric disc having contact metal layers.

FIG. 4 schematically illustrates a method of fabricating a thermoelectric disc in which contact metal layers are hot pressed onto a thermoelectric material.

FIG. 5 is a scanning electron microscope (SEM) image of a BiTe-based thermoelectric leg having nickel contact layers formed by hot pressing.

FIG. 6 schematically illustrates an experimental setup for testing the contact resistance of various thermoelectric legs with metal contact layers.

FIG. 7 is a plot of voltage (which is proportional to contact resistance) vs. distance for a p-type BiTe thermoelectric element having nickel contact layers fabricated in accordance with an embodiment method.

FIGS. 8A-8D are SEM images (FIGS. 8A-8B) and energy dispersive spectroscopy (EDS) plots (FIGS. 8C-8D) of a p-type BiTe thermoelectric element having nickel contact layers formed by hot pressing.

FIG. 9 is a plot of voltage vs. distance for an n-type BiTe thermoelectric element having nickel contact layers formed by hot pressing.

FIGS. 10A-10D are SEM images (FIGS. 10A-10B) and EDS plots (FIGS. 10C-10D) of an n-type BiTe thermoelectric element having nickel contact layers formed by hot pressing.

FIGS. 11A and 11B are plots showing the percent change in device resistance and device efficiency over time for a group of comparative devices having contact metal layers formed by conventional methods (FIG. 11A) and embodiment devices having contact metal layers formed by hot pressing (FIG. 11B).

FIGS. 12A and 12B are plots showing the percent change in contact resistance and device efficiency over time for a group of embodiment devices having contact metal layers formed by hot pressing (FIG. 12A) and a group of commercially-available comparative devices having contact metal layers formed by thermal spray (FIG. 12B).

FIG. 13 is a plot of voltage vs. distance for an n-type half-Heusler thermoelectric element having titanium contact layers formed by hot pressing.

FIG. 14A is a SEM image of an n-type half-Heusler thermoelectric element having titanium contact layers formed by hot pressing.

FIG. 14B is an EDS plot for the n-type half-Heusler thermoelectric element having titanium contact layers formed by hot pressing.

FIG. 14C is a magnified SEM image with an EDS spectra overlay for the n-type half-Heusler thermoelectric element having titanium contact layers formed by hot pressing.

FIGS. 15A-15C are SEM images of a thermoelectric element having an interlayer between an n-type half-Heusler material and a titanium contact layer.

FIG. 16 is a plot of voltage vs. distance for a p-type half-Heusler thermoelectric element having titanium contact layers formed by hot pressing.

FIG. 17A is a SEM image of a p-type half-Heusler thermoelectric element having titanium contact layers formed by hot pressing.

FIG. 17B is an EDS plot for the p-type half-Heusler thermoelectric element having titanium contact layers formed by hot pressing.

FIG. 17C is a magnified SEM image with an EDS spectra overlay for the p-type half-Heusler thermoelectric element having titanium contact layers formed by hot pressing.

FIGS. 18A-18C are SEM images of a thermoelectric element having an interlayer between a p-type half-Heusler material and a titanium contact layer.

FIGS. 19A and 19B illustrate unicouples of thermoelectric material legs bonded to a header via a metal contact layer (FIG. 19A) and via a direct bonding process (FIG. 19B).

FIG. 20 is an optical micrograph of a pair of half-Heusler thermoelectric material legs direct bonded to a metal header using a silver-copper brazing material.

FIG. 21A and FIG. 21B are scanning electron microscope (SEM) images of a bonding area between a metal header and a p-type (FIG. 21A)/n-type (FIG. 21B) half-Heusler thermoelectric material leg joined by an Ag—Cu brazing material.

FIG. 22A and FIG. 22B are plots of voltage vs. distance for both p-type (FIG. 22A) and n-type (FIG. 22B) half-Heusler thermoelectric legs that are direct bonded to a metal header by brazing.

FIG. 23 is a plot showing the percent change in device resistance and device power output over time for embodiment devices made by direct bonding process (FIG. 19B).

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Various embodiments include methods of fabricating thermoelectric elements, as well as thermoelectric elements manufactured in accordance with the embodiment methods.

In thermoelectric power generation and cooling, bulk thermoelectric materials may be fabricated into discrete elements, such as posts or “legs.” A thermoelectric device for power generation or cooling may comprise plural sets of two thermoelectric elements—one p-type and one n-type semiconductor converter post or leg which are electrically connected to form a p-n junction. For electricity generation, the thermoelectric converter materials can comprise, but are not limited to, one of: Bi₂Te₃, Bi₂Te₃₋ₓSeₓ (n-type)/Biₓ Se₂₋ₓTe₃ (p-type), SiGe (e.g., Si₈₀Ge₂₀), PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, half-Heusler materials (e.g., Hf_{1+d-x-y}ZrₓTi_{y}NiSn_{1+d-z}Sb_{z}, where 0≦x≦1.0, 0≦y≦1.0, 0≦z≦1.0, and −0.1≦d≦0.1, such as Hf_{1-x-y}ZrₓTi_{y}NiSn_{1-z}Sb_{z}, where 0≦x≦1.0, 0≦y≦1.0, and 0≦z≦1.0 when d=0, and/or Hf_{1+d-x-y}ZrₓTi_{y}CoSb_{1+d-z}Sn_{z}, where 0≦x≦1.0, 0≦y≦1.0, 0≦z≦1.0, and −0.1≦d≦0.1, such as Hf_{1-x-y}ZrₓTi_{y}CoSb_{1-z}Sn_{z}, where 0≦x≦1.0, 0≦y≦1.0, and 0≦z≦1.0 when d=0) and combinations thereof. The materials may comprise compacted nanoparticles or nanoparticles embedded in a bulk matrix material. For example, such materials are described in U.S. patent application Ser. No. 11/949,353 filed Dec. 3, 2007, which is incorporated herein by reference in its entirety.

In a conventional method for fabricating thermoelectric elements, bulk thermoelectric material is formed into a solid body, such as a disk, via an ingot growth technique. Alternatively, the bulk thermoelectric material may be in the form of small particles (e.g., powder). The particles, which may be nano-sized and/or micro-sized, are then consolidated (i.e., densified) to form a thick solid disk or slab having a thickness of 10 mm or more, such as 100-500 mm, using a hot-press or similar compaction process. As used herein, a “nanoparticle” or “nano-sized” structure, generally refers to material portions, such as particles, whose dimensions are less than 1 micron, preferably less than about 100 nanometers. For example, nanoparticles may have an average cross-sectional diameter in a range of about 1 nanometer to about 0.1 micron, such as 10-100 nm. A “microparticle” or “micro-sized” structure generally refers to material portions, such as particles, whose dimensions are less than about 100 micron. For example, microparticles may have an average cross-sectional diameter in a range of about 1 to 100 microns.

In either of the conventional fabrication methods, the solid disk of thermoelectric material must then undergo further processing to produce a thermoelectric element (i.e., a “leg”) having the desired size and shape. Typically, the disk is sliced along its thickness dimension to form a plurality of thin (e.g., 0.5 to 5 mm thick) wafers. The disk may be sliced to provide a wafer having a thickness dimension equal to the thickness of the finished thermoelectric element. The wafer is then diced along its length and width dimensions to produce the thermoelectric elements, which are typically in the millimeter size range.

The process of slicing the thermoelectric material disk through its thickness dimension for form wafers results in unavoidable yield losses. Each cut through the thickness dimension of the disk results in a loss of approximately 0.2 mm of the thermoelectric material. This is known as “kerf” loss, and can result in significant yield loss of the thermoelectric material. Further losses occur when the thermoelectric material disk is diced into individual thermoelectric element, particularly along the edges of the disk (i.e., edge loss). Overall yield losses may be approximately 9%.

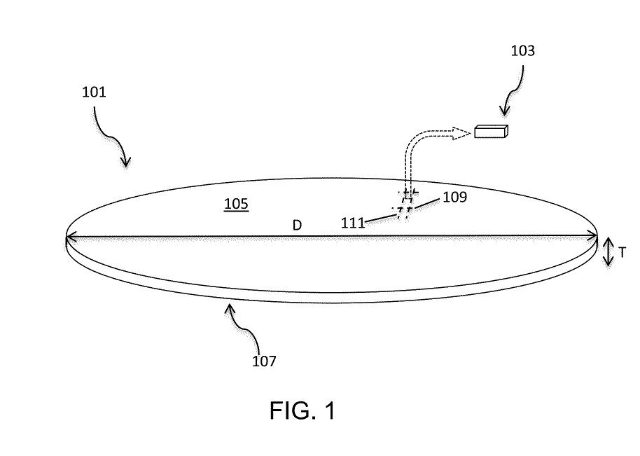

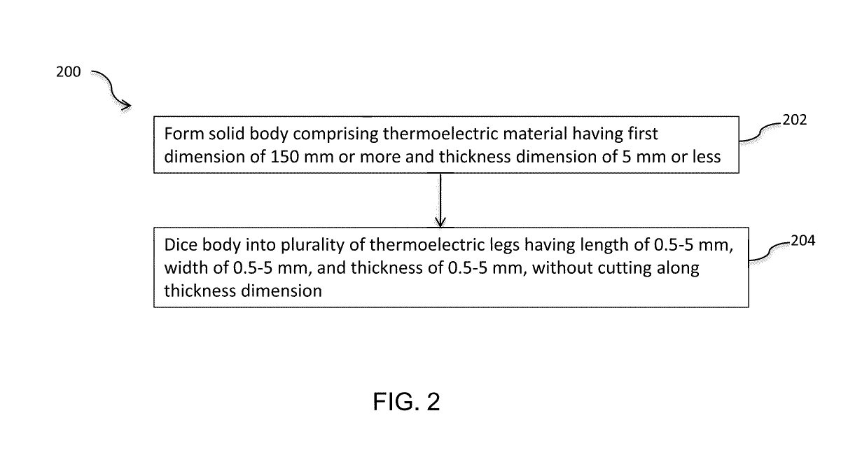

Various embodiments relate to methods of fabricating thermoelectric elements with reduced yield losses. FIG. 1 illustrates a thermoelectric material solid body 101 and thermoelectric element 103 according to one embodiment. FIG. 2 is a process flow diagram illustrating an embodiment method 200 for fabricating a thermoelectric element. In step 202 of embodiment method 200, a thermoelectric material is formed into solid body having first dimension of 150 mm or more (e.g., 150-450 mm, such as 200-300 mm) and a thickness dimension of 5 mm or less. The first dimension may be a length or width dimension. For example, when the solid body 101 has a circular shape (e.g., a disc wafer) such as shown in FIG. 1, the first dimension is the diameter, D, of the body 101. The thickness dimension of 5 mm or less (e.g., 0.5 to 5 mm) may be substantially equal to the final thickness of the thermoelectric elements 103 produced from the solid body 101 (i.e., thermoelectric material wafer).

In various embodiments, the solid body 101 may be formed by compacting particles of semiconductor thermoelectric material. The particles may be, for example, a powder comprising nano-sized and/or micro-sized particles. The particles may be consolidated to form the solid body 101 by hot pressing (i.e., simultaneous application of elevated pressure and temperature). The solid body 101 may have contact layers of a metal material (e.g., nickel, titanium, etc.) extending over the major surfaces 105, 107 of the body 101. As described in further detail below, the contact metal layers may be adhered to the thermoelectric material at the same time that the thermoelectric material is consolidated, such as by hot pressing metal powder or metal foil layers to nano-sized and/or microsized thermoelectric material particles.

In step 204 of embodiment method 200, the solid body 101 of thermoelectric material, which may optionally include contact metal layer(s) is diced into a plurality of thermoelectric elements 103 (i.e., legs) without cutting through the thickness dimension of the body 101 (i.e., without dicing parallel to surface 105 and 107 planes). This is schematically illustrated in FIG. 1 by the dashed lines 109, 111 indicating a plurality of parallel and transverse cuts that may be made to separate the body 101 into a plurality of thermoelectric elements, such as element 103. In this embodiment, no cuts are made along the thickness dimension (T) of the body 101. In various embodiments, the length and width dimensions of each element 103 may each be between about 0.5 and 5 mm. The thickness dimension of the element 103 may be determined by the thickness of the solid body 101 from which the element 103 was separated, and may be between about 0.5 and 5 mm.

By forming the solid body 101 into a shape having a thickness dimension that is the same as the thickness of the finished thermoelectric element, no cuts need to be made along the thickness of the body 101 and kerf losses may be avoided. Furthermore, the large diameter of the solid body 101 (e.g., 150 mm or more) minimizes the edge loss when the body is diced into individual elements. Total losses may be approximately 1% or less of the thermoelectric material. Losses may be further minimized when the solid body 101 is formed with a square or rectilinear shape when viewed from the top (i.e., normal to surface 105) instead of the circular wafer shape shown in FIG. 1.

Further embodiments include methods for depositing contact metal layer(s) on thermoelectric materials to fabricate a thermoelectric device. One or more metal layers may be hot pressed directly onto the thermoelectric material during powder consolidation, thus eliminating a separate metallization step. This method may be used for a variety of thermoelectric materials, such as Bismuth Telluride based alloys and half-Heusler alloys. In embodiments, the method allows deposition of thick metal contact layers on the thermoelectric materials, which may be needed for electrode joining and to prevent metal diffusion into the thermoelectric materials. In addition, the metal contact layer may have very strong shear and tensile strength. Conventional methods for forming thick metal layers, such as thermal spray, sputtering and plating, provide inferior adhesion strength to nano/micro-structured thermoelectric alloys formed by hot pressing nano or micro sized powders. In various embodiments, the present method provides a solution to make modules (both power generation and cooling) from nano/micro-structured thermoelectric materials which have high adhesion strength and thick metal contact layers.

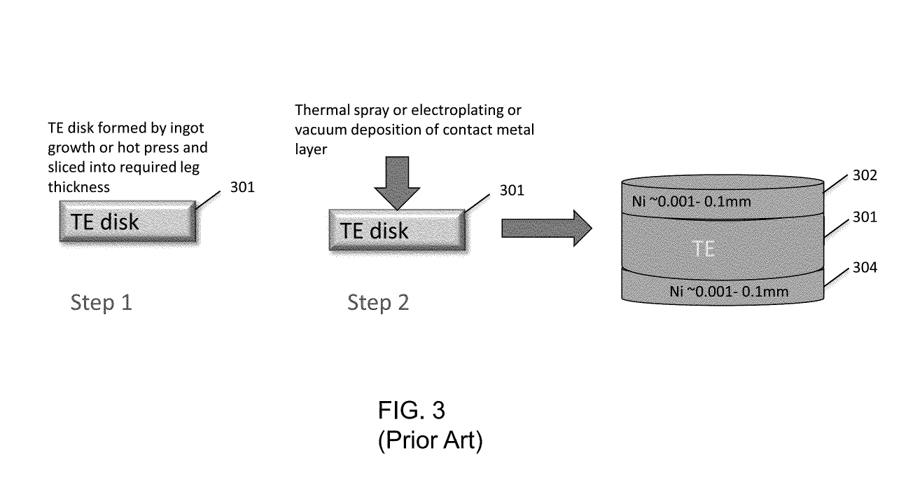

In conventional methods for contact metallization, a thermoelectric material is formed into a solid body, such as a disk 301 as shown in FIG. 3, having a desired size and shape. The disk may be formed by a known technique, such as via ingot growth or by hot pressing of nano-/micro-structured thermoelectric materials, and is then sliced into the desired leg thickness, such as shown in FIG. 3. Contact metal layers 302, 304 are formed on the surfaces of the TE disk via thermal spray, electroplating, or vacuum deposition (e.g., sputtering) to form the TE element 306 shown in FIG. 3. The metal layers (e.g., Ni) typically have a thickness of 0.001-0.1 mm. When the metal layer is deposited by electroplating, the thickness is limited to ˜10 microns. Thermal spray enables deposition of metal layers with thickness up to about 100 microns, but cannot be applied to nano/micro-structured thermoelectric materials with sufficient adhesion strength. Vacuum deposition is a more expensive process that deposits metal layers having a thickness of only a few microns. In the conventional methods, the typical metal contact adhesion strength is on the order of 10 MPa (e.g., less than 15 MPa).

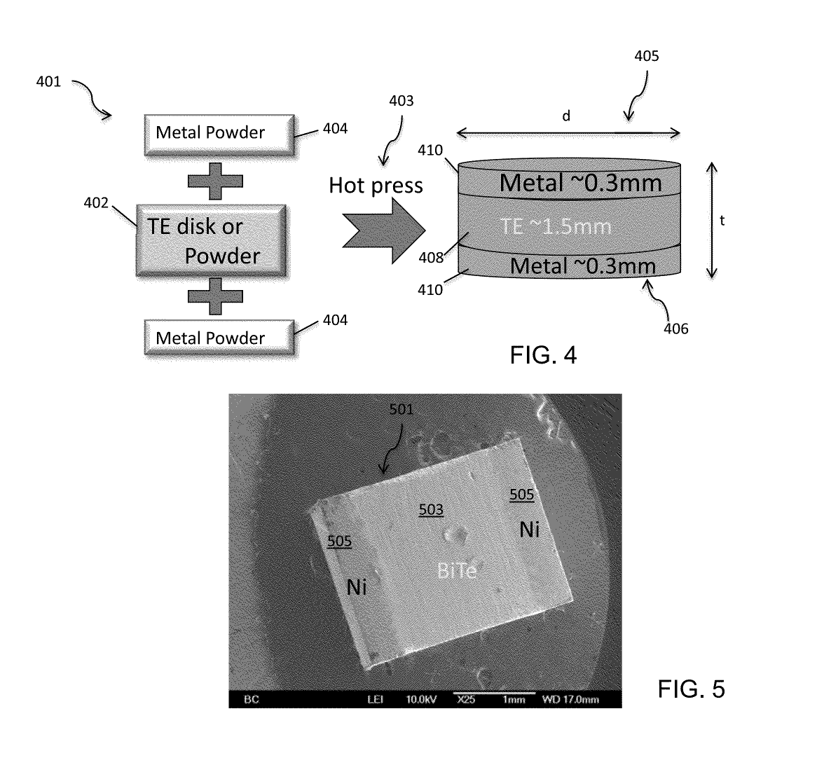

FIG. 4A schematically illustrates a method 400 of fabricating a thermoelectric device in which contact metal layer(s) are hot pressed directly onto the thermoelectric material according to an embodiment. As shown in step 401 of FIG. 4A, a thermoelectric material 402 is provided. In embodiments, the thermoelectric material 402 may be particles (e.g., a powder) of one or more suitable thermoelectric materials (e.g., p-type or n-type BiTe or half-Heusler materials, etc.). In various embodiments, the particles may be nano-sized and/or micro-sized particles. The particles may be loaded into a die cavity of a suitable hot press apparatus (not shown). A metal material 404 may be provided over and/or under one or more surfaces of the thermoelectric material 402. The metal material may be a metal powder, (e.g., a millimeter sized, micro-sized and/or nano-sized powder), or a metal foil, for example.

The combined thermoelectric and metal materials 402, 404 may then undergo a hot pressing treatment (i.e., simultaneous application of elevated pressure and temperature) as shown in step 403. The hot pressing treatment may consolidate and densify the particles to produce a solid body 406 in a desired size and shape. In one embodiment, the hot pressing may have a peak temperature in a range of 250-1500° C. and a pressure of 10-200 MPa. In some embodiments, such as for hot pressing BiTe-based thermoelectric materials, the peak temperature may be in a range of 300-550° C. In other embodiments, such as for hot pressing half-Heusler-based thermoelectric materials, the peak temperature may be in a range of 800-1200° C. The duration of the hot press step may be 30 seconds to 2 hours, such as between about 1 and 30 minutes (not including ramping times).

The hot pressing treatment produces a solid body 406 (e.g., a wafer, slab or disk) having contact metal layer(s) 410 over two sides of a thermoelectric material layer 408, as shown in step 405. FIG. 5 is a scanning electron microscope (SEM) image of a BiTe-based thermoelectric device 501 having Ni contact layers 505 formed on a thermoelectric material 503 by hot pressing. In embodiments where the thermoelectric material is a powder, the hot pressing step may be used both to consolidate (e.g., densify) the thermoelectric powder as well as to apply contact metal layers in a single, cost-effective step. In other embodiments, the thermoelectric material may be previously formed into a solid body (e.g., a disk), and the hot pressing step may be used to adhere metal contact layers to the body.

In embodiments, the hot pressing step may press the thermoelectric 402 and metal 404 materials to a thickness, t, that corresponds to the thickness of the fully-fabricated thermoelectric elements (i.e., legs). A typical thickness is 0.5-5 mm. Pressing the materials to the final device thickness may eliminate kerf loss, as discussed above. The diameter (or width for non-cylindrical bodies), d, of the disk 406 may be any suitable size, e.g., from ˜1 mm to any arbitrary size, such as 150-300 mm, for example. The disk 406 may be diced to form TE legs having desired dimensions (e.g., thickness of 0.5-5 mm, width of 0.5-5 mm, and length of 0.5-5 mm).

The thickness of the thermoelectric material layer 408 may be 0.5-5 mm, such as 1.5-2 mm. The thickness of the metal layers 406 may be 0.05-1 mm, such as 0.3-0.5 mm. A thick metal layer (e.g., greater than 0.1 mm, such as 0.1 to 1 mm, e.g., 0.5 to 1 mm) may enable the layers 410 to be joined to another structure or surface, such as an electrode, by welding. A thick metal layer may be important in high temperature operation. If the contact layer is too thin, diffusion of solder or electrode material into the TE material may ruin the performance of the device. Furthermore, a thick contact layer may enable an electrode to be welded to the contact layer without soldering or brazing.

In various embodiments, the hot pressing step is performed such that an interlayer is formed between the contact metal layer and the thermoelectric material. The interlayer may be a multiphase layer that has a composition that includes the metal of the contact layer and at least one component of thermoelectric material. The interlayer may have a thickness of 1-100 μm.

The interlayer may improve the adhesion strength, including tensile and shear strength, of the contact metal layer on the thermoelectric material. In embodiments, the adhesive strength of the contact metal layer on the thermoelectric material may be greater than 10 MPa, such as 12 MPa or more (e.g., 15-35 MPa). The interlayer may further help to achieve very low contact resistance and improved thermal cycling and stability during operation. The contact resistance of a thermoelectric element produced in accordance with the present hot press method may be less than 15 μΩ-cm², such as 10 μΩ-cm² or less (e.g., 1-5 μΩ-cm², such as 1-2 μΩ-cm²).

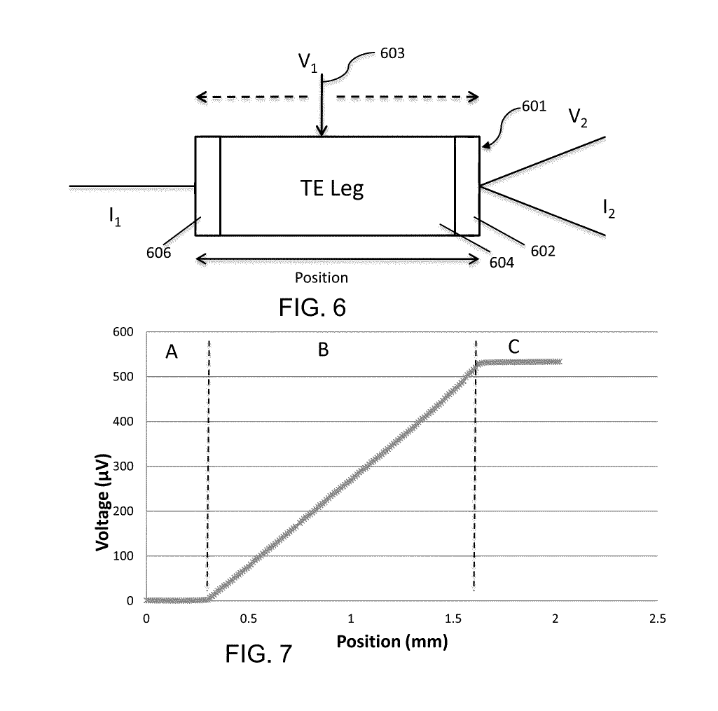

FIG. 6 schematically illustrates an experimental setup for testing the contact resistance of various TE devices (legs) formed by the hot pressing method as described above. A current is provided through the TE device 601 via current leads, I₁ and I₂, and the voltage drop across sensing terminals, V₁ and V₂, is measured as one of the sensing terminals (e.g., probe 603) is moved to different positions along the length of the element 601 (e.g., from a first contact metal layer 602, along the TE material 604, to a second contact metal layer 606), as indicated by the dashed arrows. The voltage measured by the probe 603 is proportional to the resistance of the element 601, and may be used to determine the contact resistance of the device 601.

FIG. 7 is a plot of voltage (which corresponds to contact resistance) vs. distance for a p-type BiTe thermoelectric element having nickel contact layers formed by hot pressing. In the plot, Region A (0 to ˜0.3 mm) corresponds to a first nickel contact layer, Region B (˜0.3 to ˜1.6 mm) corresponds to the p-type BiTe layer, and Region C (˜1.6 to ˜2.0 mm) corresponds to the second nickel contact layer. It is noted that the plot of measured voltage (which are proportional to resistance) includes substantially no gap in the transition between Region A and Region B, as well as substantially no gap in the transition between Regions B and C. This indicates that the contact resistance of the device is low (e.g., ˜2 μΩ-cm²). In this example, the tensile strength of the Ni contact layer on the p-type BiTe thermoelectric material was ˜30 MPa.

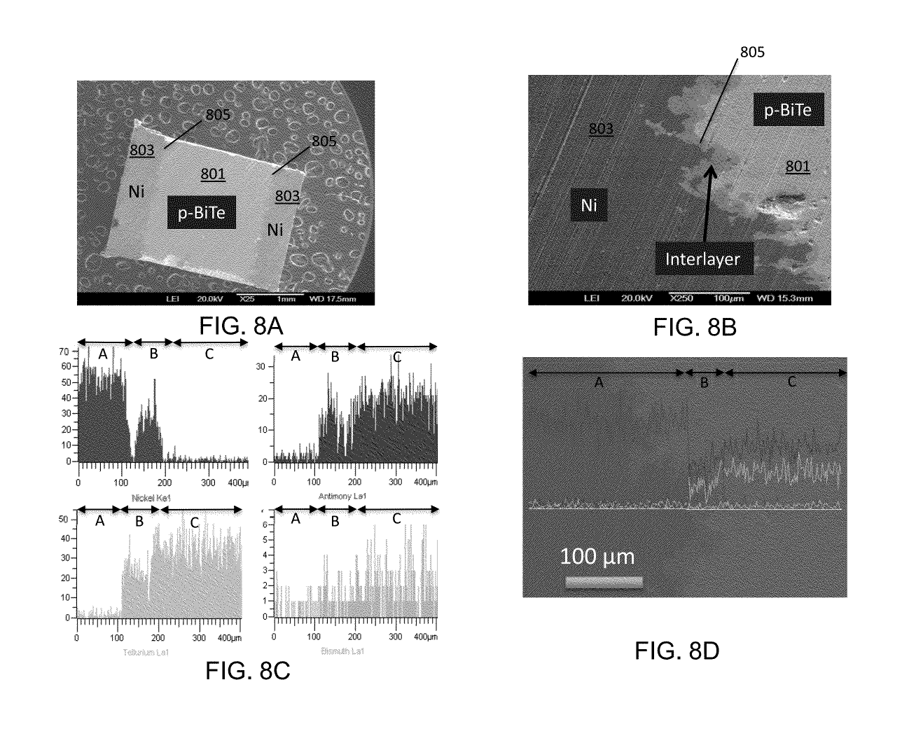

FIGS. 8A-8D are SEM images (FIGS. 8A-8B) and energy-dispersive spectroscopy (EDS) plots (FIGS. 8C-8D) of a p-type BiTe (e.g., Sb doped Bi₂Te₃) thermoelectric element having nickel contact layers formed by hot pressing, as discussed above. An interlayer 805 is visible between the p-BiTe thermoelectric material 801 and the Ni contact layers 803 in FIGS. 8A-8B. The interlayer 805 corresponds to Region B in the EDS plots of FIGS. 8C-8D, while the nickel contact layer 803 and the p-type BiTe thermoelectric material layer 801 correspond to Regions A and C, respectively. The EDS plots indicate that the interlayer 805 in this example has a thickness of about 50 μm and contains nickel and at least one constituent of the thermoelectric material (i.e., bismuth, tellurium and/or antimony in this example). Further, the interlayer 805 acts as a barrier layer such that metal material from the contact layer 803 is inhibited from diffusing into the thermoelectric layer 801. As shown in FIG. 8C-8D, for example, Region C, corresponding to the thermoelectric material layer 801, is substantially free of nickel.

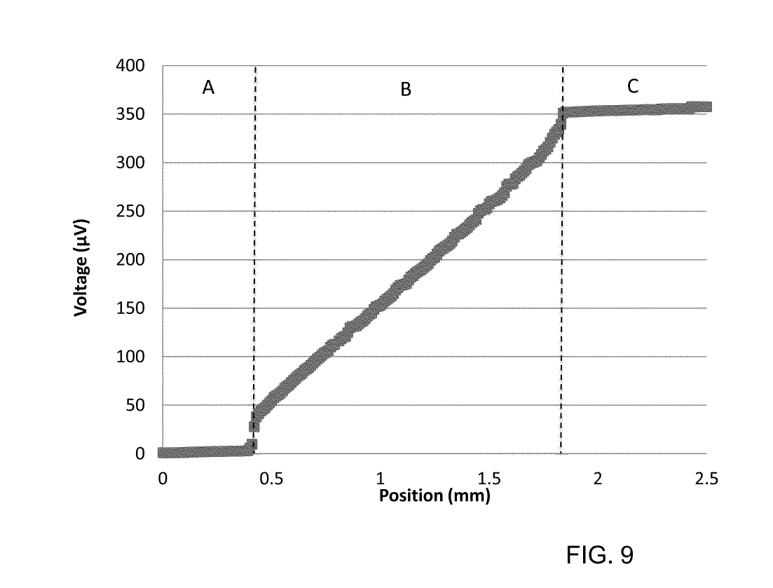

FIG. 9 is a plot of voltage vs. distance for an n-type BiTe (e.g., Se doped Bi₂Te₃) thermoelectric element having nickel contact layers formed by hot pressing. In the plot, Region A (0 to ˜0.4 mm) corresponds to a first nickel contact layer, Region B (˜0.4 to ˜1.8 mm) corresponds to the n-type BiTe layer, and Region C (˜1.8 to ˜2.5 mm) corresponds to the second nickel contact layer. In this example, the small gaps in the transitions between Regions A and B and Regions B and C indicate that the device has a contact resistance of 10 μΩ-cm². In this example, the tensile strength of the Ni contact layer on the n-type BiTe thermoelectric material was ˜17 MPa.

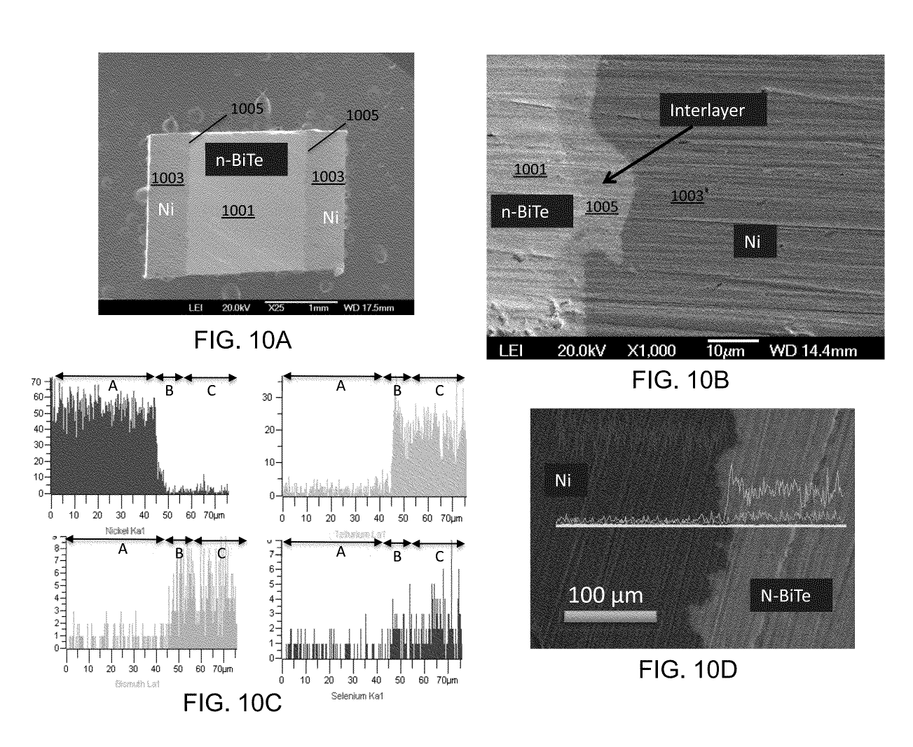

FIGS. 10A-10D are SEM images (FIGS. 10A-10B) and EDS plots (FIGS. 10C-10D) of an n-type BiTe thermoelectric element having nickel contact layers formed by hot pressing, as discussed above. An interlayer 1005 is visible between the n-BiTe thermoelectric material 1001 and the Ni contact layers 1003 in FIGS. 8A-8B. The interlayer 1005 corresponds to Region B in the EDS plots of FIGS. 10C-10D, while the nickel contact layer 1003 and the n-type BiTe thermoelectric material layer 1001 correspond to Regions A and C, respectively. The EDS plots indicate that the interlayer 1005 in this example has a thickness of about 10 μm and contains nickel and at least one constituent of the n-type thermoelectric material (i.e., bismuth, tellurium and/or selenium in this example). Further, the interlayer 1005 acts as a barrier layer such that metal material from the contact layer 1003 is inhibited from diffusing into the thermoelectric layer 1001. As shown in FIG. 10C-10D, for example, Region C, corresponding to the thermoelectric material layer 1001, is substantially free of nickel.

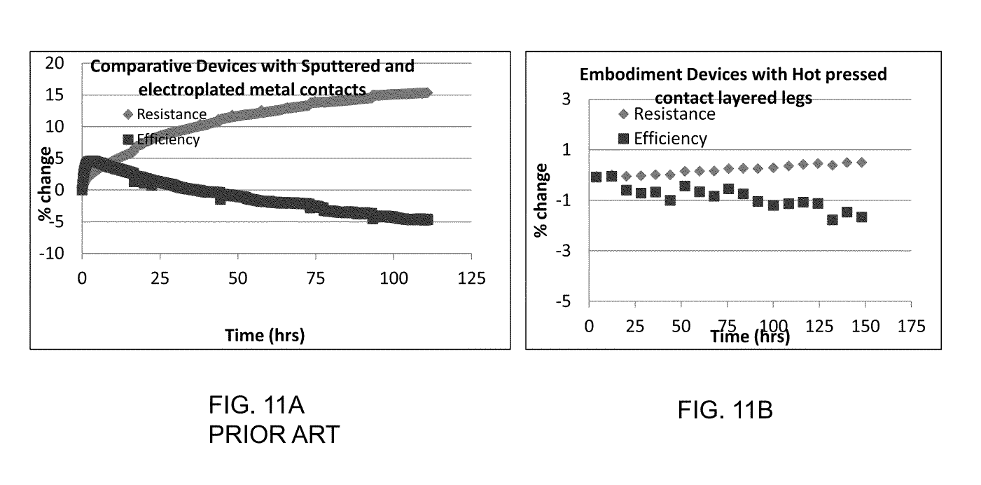

FIGS. 11A and 11B are plots showing the percent change in contact resistance and device (including thermal absorber) efficiency over time for two groups of thermoelectric devices. The first group of devices (Comparative Devices), plotted in FIG. 11A, are BiTe thermoelectric generator devices in which the metal contact layers were provided using conventional sputtering and electroplating. In the Comparative Devices, the contact metal layers include a 20 nm Ti layer formed by sputtering, followed by a 400 nm Ni layer formed by sputtering, and a 3 μm Ni layer formed by electroplating. The second group of devices (Embodiment Devices), plotted in FIG. 11B, are BiTe thermoelectric generator devices that have been formed by hot pressing 300 μm Ni contact metal layers, as described above, but are otherwise identical to the Comparative Devices. As is evident from the plots, the Embodiment Devices exhibit greater stability over time in terms of contact resistance and device efficiency than the Comparative Devices. As shown in FIG. 11B, the contact resistance increased by less than 1% (e.g., 0.1-0.5% over 100-150 hours) and device efficiency decreased by less than 2% (e.g., 1.5 to 1.9% over 100-150 hours).

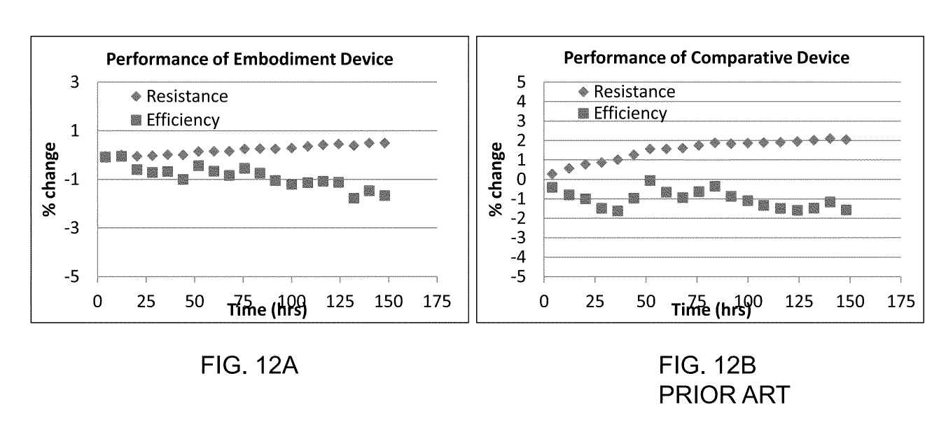

FIGS. 12A and 12B are plots showing the percent change in contact resistance and device efficiency over time for two groups of thermoelectric generator devices: the Embodiment Devices (FIG. 12A, which is the same as FIG. 11B) having contact metal layers formed by hot pressing as described above, and a second group of comparative devices (FIG. 12B). The second group of comparative devices shown in FIG. 12B are commercially-available thermoelectric devices having contact metal layers formed by thermal spray. As seen from the plots, the contact resistance of the Embodiment Devices is more stable than that of the comparative devices, and the Embodiment Devices exhibit similar efficiency as the comparative devices.

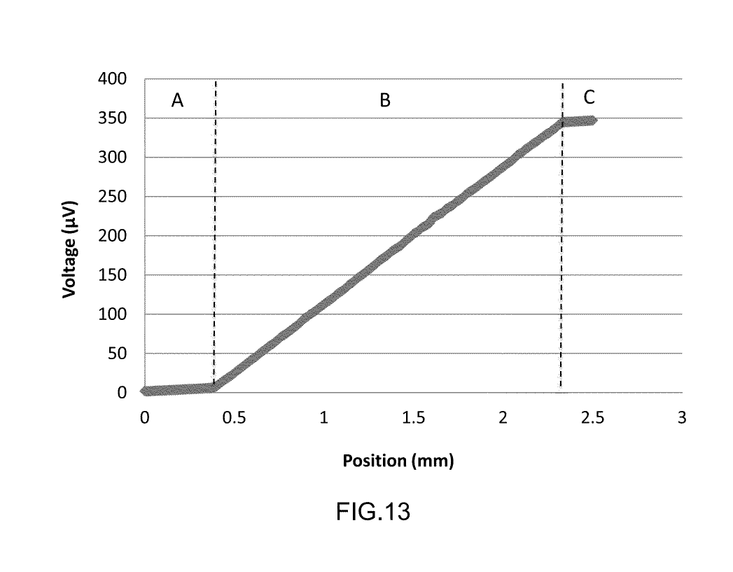

FIG. 13 is a plot of voltage vs. distance for an n-type half-Heusler thermoelectric element having metal contact layers formed by hot pressing. The n-type half-Heusler materials in this example are Hf_{1-x-y}ZrₓTi_{y}NiSn_{1-z}Sb_{z}, where 0≦x≦1.0, 0≦y≦1.0, and z=0.2. The contact layer is titanium. Region A (0 to ˜0.4 mm) corresponds to a first titanium contact layer, Region B (˜0.4 to ˜2.3 mm) corresponds to the n-type half-Heusler layer, and Region C (˜2.3 to ˜2.6 mm) corresponds to the second titanium contact layer. It is noted that the plot of measured voltages (which are proportional to resistance) includes substantially no gap in the transition between Region A and Region B, as well as substantially no gap in the transition between Regions B and C. This indicates that the contact resistance of the device is low (e.g., ˜1 μΩ-cm²). In this example, the tensile strength of the Ti contact layer on the n-type half-Heusler thermoelectric material was ˜17 MPa.

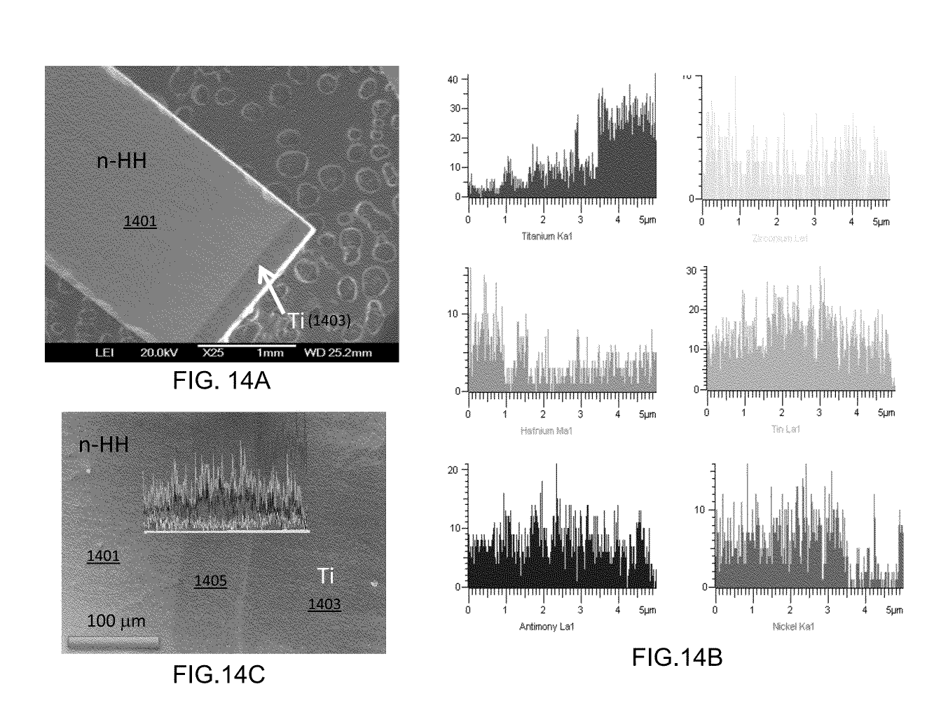

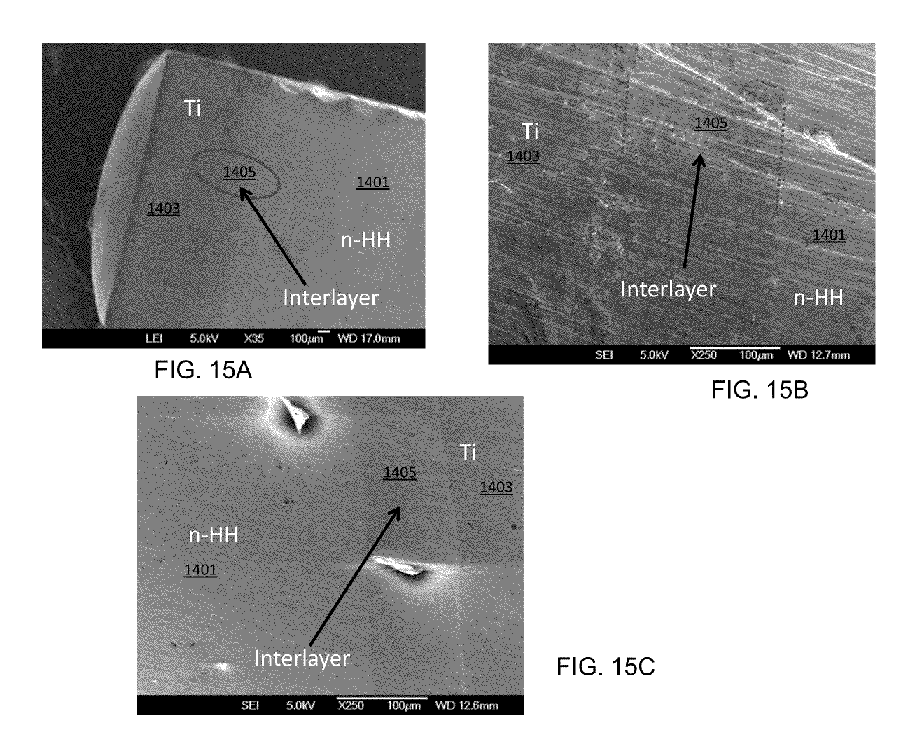

FIG. 14A is a SEM image of an n-type half-Heusler thermoelectric element having titanium contact layers formed by hot pressing, as discussed above. FIG. 14B shows EDS plots for the element, and FIG. 14C is a magnified SEM image of the element with an EDS spectra overlay. FIG. 14C shows the existence of an interlayer 1405 between the Ti contact layer 1403 and the n-type half-Heusler layer 1401. The interlayer 1405 is also evident in the SEM images of FIGS. 15A-15C. The interlayer 1405 in this embodiment has a thickness of around 100 μm.

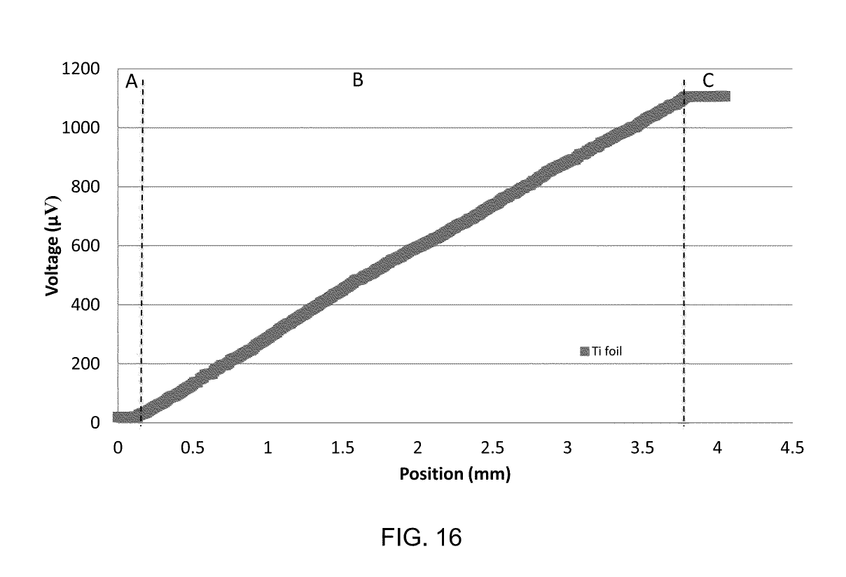

FIG. 16 is a plot of voltage vs. distance for a p-type half-Heusler thermoelectric element having metal contact layers formed by hot pressing. The p-type half-Heusler materials in this example is Hf_{0.5}Zr_{0.5}CoSn_{0.2}Sb_{0.8}. The contact layer is titanium foil that is adhered to the thermoelectric material by hot pressing. Region A (0 to ˜0.2 mm) corresponds to a first titanium contact layer, Region B (˜0.2 to ˜3.8 mm) corresponds to the p-type half-Heusler layer, and Region C (˜3.8 to ˜4.1 mm) corresponds to the second titanium contact layer. It is noted that the plot of measured voltages (which are proportional to resistance) includes substantially no gap in the transition between Region A and Region B, as well as substantially no gap in the transition between Regions B and C. This indicates that the contact resistance of the device is low (e.g., ˜1 μΩ-cm²). In this example, the tensile strength of the Ti contact layer on the p-type half-Heusler thermoelectric material was ˜17 MPa.

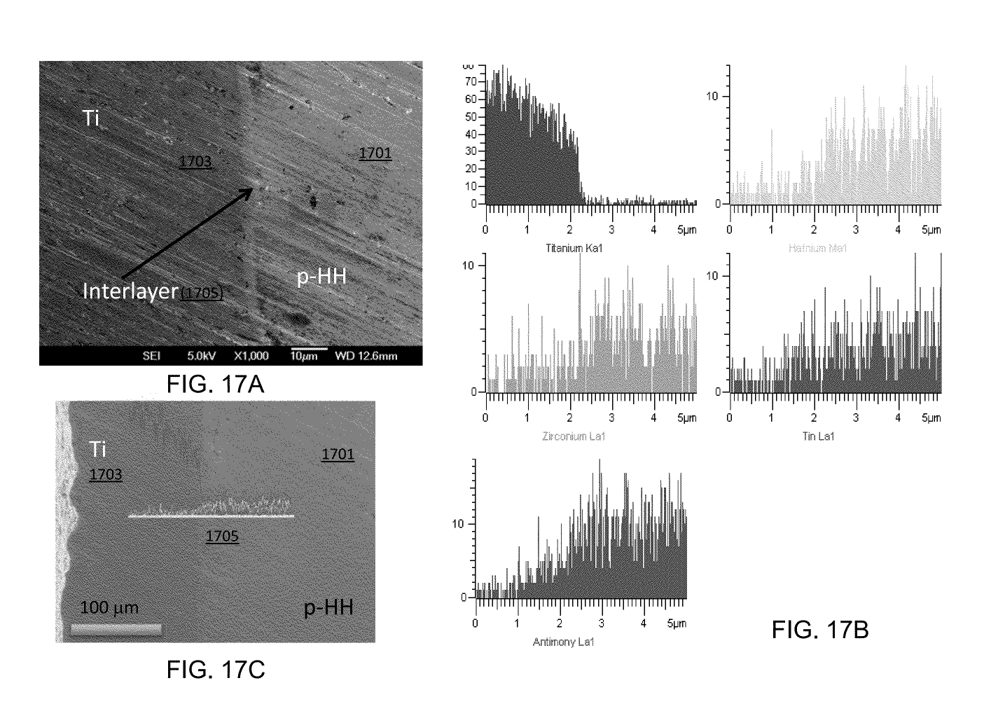

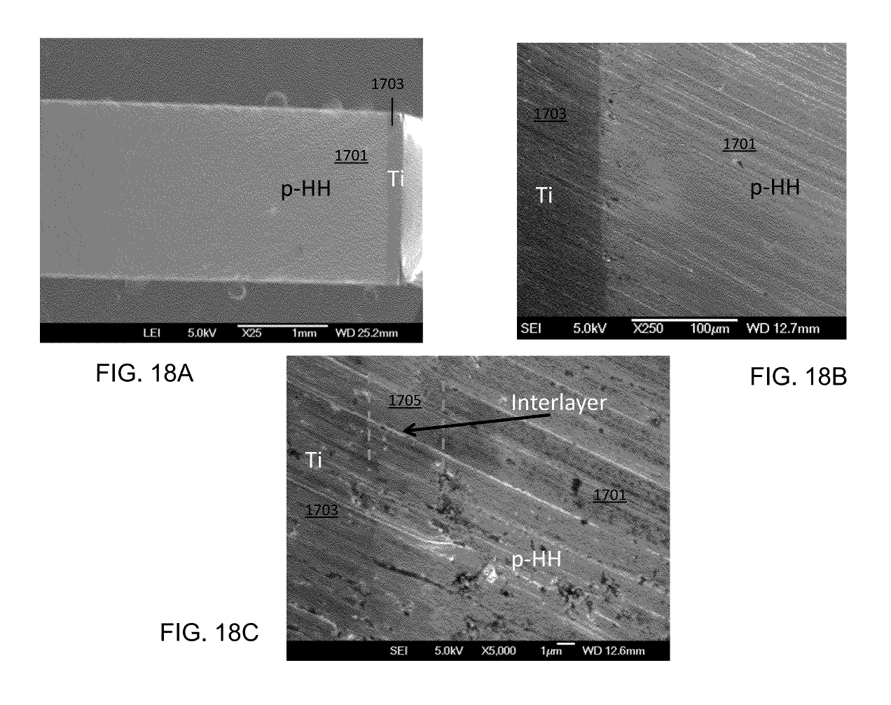

FIG. 17A is a SEM image of a p-type half-Heusler thermoelectric element having titanium contact layers formed by hot pressing, as discussed above. FIG. 17B shows EDS plots for the element, and FIG. 17C is a magnified SEM image of the element with an EDS spectra overlay. FIGS. 17A and 17C show the existence of an interlayer 1705 between the Ti contact layer 1703 and the p-type half-Heusler layer 1701. The interlayer 1705 is also evident in the SEM images of FIGS. 18A-18C. The interlayer 1705 in this embodiment has a thickness of around 5 μm.

### ADDITIONAL EMBODIMENTS

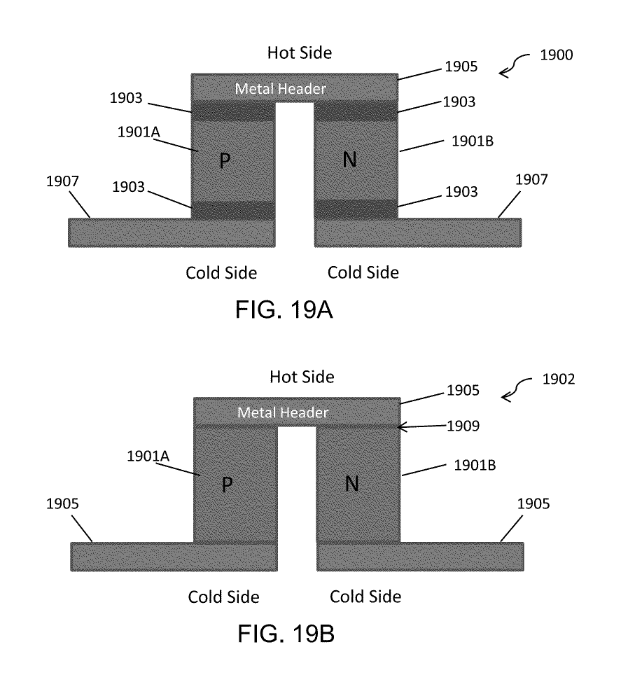

A unicouple 1900 (i.e., a basic unit of a thermoelectric converter device) may include a p-type thermoelectric material leg 1901A and an n-type thermoelectric material leg 1901B, as shown in FIG. 19A. Each leg 1901 may have metal contact layer(s) 1903 at one or both ends of the legs. The metal contact layers 2703 may be formed via thermal spray, electroplating, or vacuum deposition (e.g., sputtering) or by a hot press method as described above. The pair of legs 1901A, 1901B are thermally and electrically coupled at a first (e.g., hot) end, e.g., to form a junction such as a pn junction or p-metal-n junction. The junction can be a header 1905 made of an electrically conductive material, such as a metal. Electrical connectors 1907 (e.g., metal connectors) may be connected to the second (cold) ends of the thermoelectric legs 1901A, 1901B, and may be laterally offset from the header connector 1905 such that for each pair of n-type and p-type legs, one leg 1901A (e.g., a p-type leg) contacts a first connector 1907, and the other leg 1901B (e.g., an n-type leg) contacts a second connector 1907. Each connector 1907 may connect the thermoelectric element pair with an adjacent pair of p-type and n-type thermoelectric material legs (not shown) or to an electrically conductive lead (also not shown) which may be used to extract electrical energy generated by the unicouple 1900.

In a typical process for fabricating a unicouple 1900 as shown in FIG. 19A, the metal contact layers 1903 are formed over the thermoelectric material 1901A, 1901B using a suitable process, such as by hot pressing, and the metal contact layers 1903 are bonded to the metal header 1905 and/or to the metal connector 1907 by soldering, brazing or other bonding techniques. In one embodiment, the thermoelectric material legs 1901A, 1901B are comprised of p-type and n-type half-Heusler thermoelectric materials, the metal contact layers 1903 are titanium, and the header 1905 and connectors 1907 are copper.

The formation of pre-fabricated metal contact layers (e.g., metal foils) over thermoelectric material by hot pressing can present certain challenges. The adhesion strength of the metal contact layer to the thermoelectric legs may not be sufficient to suppress the thermal stress around the contact area at large temperature difference across the leg, which is typical for high temperature thermoelectric applications. Further, the material or process used for the metal contact layers, such as nickel or titanium electro-less plating or thermal spaying, is expensive. In addition, the presence of the metal contact layers takes away power from the thermoelectric device (e.g., via thermal and resistive losses in the metal contacts), and in some cases up to one-third of the total power of the device may be lost due to the metal contact layers. Also, the hot press process for bonding the metal contact layer must be performed at a very high temperature (e.g., >1000° C.). Finally, metallization approach may limit the header choice because of a high thermal expansion coefficient requirement.

FIG. 19B illustrates an alternative embodiment of a unicouple 1902 in which the thermoelectric material legs 1905A, 1905B are direct bonded to the metal header 1905 and metal connectors 1907. The thermoelectric material legs 1905A, 1905B may be bonded to the metal header 1905 or connector 1907 by liquid state diffusion, such as brazing or soldering (e.g., using a coupon material which is melted and flows into a junction between the header 1905 or connector 1907 and the adjacent thermoelectric leg 1901) or by solid state diffusion (e.g., none of materials being bonded, including the thermoelectric material the metal header/connector material and an optional solid interface material goes through the melting process). Thus, using a direct bonding technique, a metal contact layer may be omitted at the interface 1907 between the thermoelectric material legs 1905A, 1905B and the metal header 1905 or connector 1907.

The direct bonded unicouple 1902 of FIG. 19B may provide higher power than the equivalent unicouple 1900 having metal contact layers 1903 as shown in FIG. 19A because there is no power loss from the metal contact layers in the direct bonded unicouple 1902. Furthermore, the inventor has discovered that direct bonded unicouples 1902 may have a high adhesion strength at the interface 1909 between the thermoelectric material legs and the header 1905 or connector 1907 (e.g., >35 MPa, such as >40 MPa, including 35-45 MPa, such as ˜45 MPa), and low contact resistance (e.g., less than 15 μΩ-cm², such as 10 μΩ-cm² or less, including 1-5 μΩ-cm², such as 1-2 μΩ-cm²). The direct bonded unicouple 1902 may also be less expensive to manufacture compared to the equivalent unicouple 1900 having metal contact layers 1903, because the cost of the material and process (e.g., Ni or Ti coating/hot pressing) for the metal contact layers 1903 may be eliminated. In addition, a direct bonding technique, such as liquid state diffusion (e.g., brazing) or solid state diffusion, may be performed at lower temperatures (e.g., <800° C.) than hot pressing a metal contact layer onto a thermoelectric material.

In various embodiments of a unicouple 1902 as shown in FIG. 19B, the thermoelectric legs 1901A, 1901B may be made of any suitable thermoelectric material, such as a half-Heusler material, Bi₂Te₃, Bi₂Te₃₋ₓSeₓ (n-type)/BiₓSe₂₋ₓTe₃ (p-type), SiGe (e.g., Si₈₀Ge₂₀), PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material, as described in U.S. patent application Ser. No. 11/949,353 filed Dec. 3, 2007, which is incorporated herein by reference. In preferred embodiments, the thermoelectric material comprises a half-Heusler material. Suitable half-Heusler materials and methods of fabricating half-Heusler thermoelectric elements which may be used in a direct bonding method may include, but are not limited to, the materials and methods described in U.S. patent application Ser. No. 13/330,216 filed Dec. 19, 2011 and Ser. No. 13/719,966 filed Dec. 19, 2012, the entire contents of both of which are incorporated herein by reference for all purposes. Half-Heuslers (HHs) are intermetallic compounds which have great potential as high temperature thermoelectric materials for power generation. HHs are complex compounds having a formula MCoSb (p-type) and MNiSn (n-type), where M can be Ti or Zr or Hf or Fe or combination of two or three of the elements. Sn and Sb can be substituted by the other one of Sn/Sb; Co and Ni by Ir and Pd or Nb.

The header 1905 and/or connector 1907 may be formed of any suitable electrically conductive material, such as a metal material, including silver, copper, nickel, a nickel-iron alloy (e.g., NiₓFe₁₋ₓ) such as INVAR®, stainless steel, aluminum, titanium, and various combinations and alloys of the same.

In one embodiment, the thermoelectric material legs 1905A, 1905B may be direct bonded to a header 1905 and/or connector 1907 using a brazing process. Brazing is a technique for joining two materials using a filler material that is heated above its melting point and flows into the interface between the two materials via alloying or capillary action. The liquid brazing material is then cooled to join the two materials together. Brazing is typically performed at a temperature sufficient to melt the brazing material without melting the materials being joined. The heating method may include furnace heating, IR heating, induction heating, current heating, etc. A brazing process is typically performed at a lower temperature than a welding process, in which the joint between two materials is melted, and may be performed at a temperature between about 450° C. and 900° C. The brazing material may be in the form of a solid rod, wire or preform that is positioned adjacent to the interface of the two materials, and may be held (e.g., pressed) against the interface as the brazing material is heated above its melting temperature. The liquefied brazing material “wicks” into the gap between the materials via alloying or capillary action to bond the materials. Suitable brazing materials may include, for example, silver, copper, a silver-copper based alloy, an aluminum alloy, a nickel alloy, a titanium alloy, etc. Soldering is a similar liquid state diffusion bonding process that is typically performed at lower temperatures (e.g., <450° C.) and may be used in various embodiments, such as in lower temperature applications (e.g., for direct bonding of lower temperature thermoelectric materials, such as BiTe, to a header/connector and/or for bonding the “cold” sides of a thermoelectric leg to a connector).

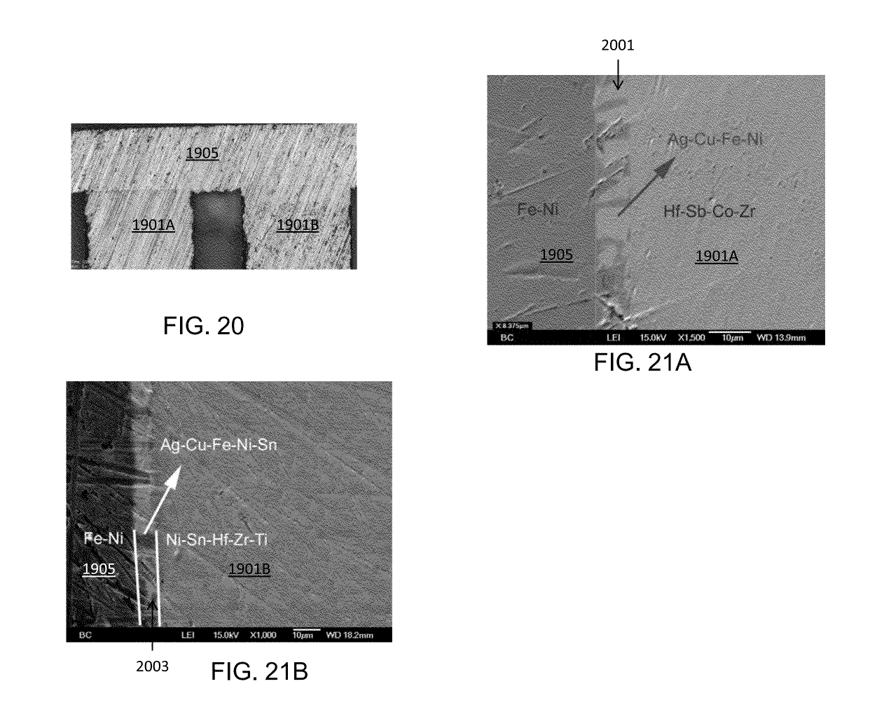

FIG. 20 is an optical micrograph of a pair of half-Heusler thermoelectric material legs 1901A, 1901B direct bonded to a metal (Fe—Ni) header 1905 using a silver-copper brazing material. As shown in FIG. 20, the bond is substantially free of cracking and voids.

FIGS. 21A and B are scanning electron microscope (SEM) images of the bonding area showing the interdiffusion between the Fe—Ni header 1905 and the p-type half-Heusler (Hf—Sb—Co—Zr containing) thermoelectric material leg 1901A (FIG. 21A) and the n-type half-Heusler (Hf—Ti—Zr—Ni—Sn containing) thermoelectric material leg 1901B. The interface regions 2001, 2003 between the header 1905 and thermoelectric material legs 1901A, 1901B include an Ag—Cu brazing material as well as the header material (Fe—Ni). The initial mechanical strength between the thermoelectric material legs 1901A, 1901B and the header material 1905 was >40 MPa (˜45 MPa) in these two examples.

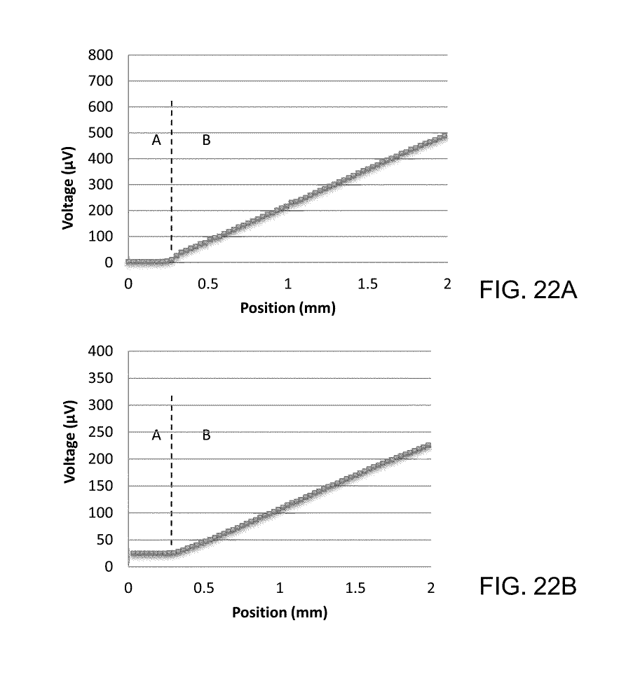

FIGS. 22A and B are plots of voltage (which corresponds to contact resistance) vs. distance for p-type (FIG. 22A) and n-type (FIG. 22B) half-Heulser thermoelectric legs that are direct bonded to a metal header by brazing. In the plots, Region A (0 to ˜0.4 mm) corresponds to the metal header, and Region B corresponds to the half-Heusler thermoelectric legs. It is noted that the plots of measured voltage (which are proportional to resistance) include substantially no gap in the transition between Region A and Region B. This indicates that the contact resistance of the device is low (e.g., 1-2 μΩ-cm² or less).

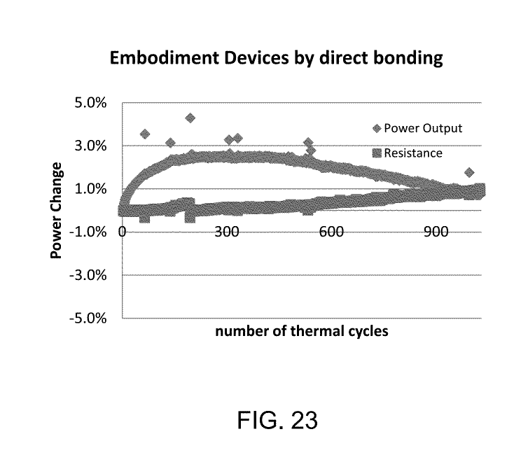

FIG. 23 is a plot illustrating data from long term testing of a thermoelectric device formed using the direct bonding (brazing) technique. The plot illustrates percent change of power output and resistance (y-axis) over 1000 thermal cycles (x-axis). As shown in FIG. 23, the embodiment device showed <1% power output degradation over 1000 cycles for twenty days. In each cycle, the hot side of the device was heated to 600° C. while the cold side of the device was at 100° C., and the device was held at 600° C. (hot side) and 100° C. (cold side) for half an hour, after which the hot side was cooled to 100° C. Overall, each cycle takes 30-40 minutes. The results indicate that the interface area between the metal header and half-Heusler material exhibits great stability over time in terms of contact resistance and device power output.

Table 1 illustrates comparison data between an Embodiment Device and a Comparison Device. The Embodiment Device is a half-Heusler thermoelectric converter device in which the thermoelectric legs are bonded to a metal header by a direct bonding (e.g., brazing) technique, as described above. The Comparison Device is an identical half-Heusler thermoelectric converter device, but with a titanium contact layer formed over the thermoelectric material legs by hot press, and the metal header is attached to the titanium contact layer by brazing.

TABLE 1

| | Comparison Device | Embodiment Device |
|---|---|---|
| Mechanical | ~17 MPa | ~40 MPa |
| Strength | | |
| Power Output | ~0.25 W | ~0.4 W |
| Compatibility | Choice of header materials | Header may be wide |
| | limited (requires good CTE | range of materials |
| | match due to lower strength) | (e.g., metals) |
| Reliability | High risk of failure in long-term | <1% power output |
| | operation (device broke during | degradation over |
| | testing) | 1000 full cycles |
| Cost | Metal contacts ~30% of | Reduced cost due |
| | material cost | to the elimination of |
| | | metal contacts |

In another embodiment, the thermoelectric material leg 1901A, 1901B may be direct bonded to a header 1905 and/or connector 1907 using solid state diffusion with or without solid interface material. The thermoelectric material may be a semiconductor material, such as a complex compound semiconductor (e.g., a half-Heusler material). In one embodiment, the header 1905 and/or connector 1907 may comprise a material that readily diffuses into a semiconductor material, such as nickel. The header 1905 and/or connector 1907 may comprise nickel, silver, copper, a nickel-iron alloy (e.g., NiₓFe₁₋ₓ) such as INVAR®, titanium, and various combinations and alloys of the same. The thermoelectric material leg 1901A, 1901B may be directly bonded to the header 1905 and/or connector 1907 by solid state diffusion without the use of an interface material between the leg(s) and the header/connector. In other embodiments, the solid state diffusion bonding may utilize a solid interface material located between the thermoelectric material leg 1901A, 1901B and the header 1905 and/or connector 1907. The solid interface material may comprise a material that readily diffuses into both the material of the thermoelectric leg (e.g., a semiconductor material, such as a half-Heusler material) and the material of the header or connector (e.g., a metal or metal alloy). The solid interface material may comprise silver, for example, and may comprise silver nanoparticles. A solid-state diffusion bonding process typically includes holding the components to be joined under a high pressure load (e.g., ˜10-100 MPa) at elevated temperature, which may be in a protective atmosphere or vacuum environment or in air. The loads are typically not sufficient to cause macro-deformation of the materials, and the temperature is generally less than the melting temperature(s) of the materials being joined, and may be, for example 0.5-0.8 of the melting point temperature of at least one material being joined. The components are bonded via interdiffusion of one or more constituent materials of the component(s). The header 1905 and/or connector 1907 may be direct bonded to one or more thermoelectric material legs 1901A, 1901B by pressing the header 1905 or connector 1907 against the leg(s) 1901A, 1901B at elevated temperature (e.g., <1200° C., such as 450-1000° C.) with or without any solid interface material.

The foregoing method descriptions are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not necessarily intended to limit the order of the steps; these words may be used to guide the reader through the description of the methods. Further, any reference to claim elements in the singular, for example, using the articles “a,” “an” or “the” is not to be construed as limiting the element to the singular.

Further, any step or component of any embodiment described herein can be used in any other embodiment.

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A method of fabricating a thermoelectric device, comprising:
bonding at least one thermoelectric material leg to at least one of a header and an electrical connector using a direct bonding process.

2. The method of claim 1, wherein the direct bonding process comprises at least one of a liquid state and a solid state diffusion bonding process.

3. The method of claim 2, wherein direct bonding process comprises a liquid state diffusion bonding process comprising at least one of brazing and soldering.

4. The method of claim 3, wherein the liquid state diffusion bonding process comprises brazing.

5. The method of claim 2, wherein the direct bonding process comprises a solid state diffusion bonding process.

6. The method of claim 5, wherein the solid state diffusion bonding process is performed without a solid interface material between the thermoelectric material leg and the at least one of a header and an electrical connector.

7. The method of claim 5, wherein the solid state diffusion bonding process is performed using a solid interface material between the thermoelectric material leg and the at least one of a header and an electrical connector.

8. The method of claim 7, wherein the solid interface material comprises silver nanoparticles.

9. The method of claim 1, wherein the thermoelectric material leg does not include a metal contact layer between the leg and the header or electrical connector.

10. The method of claim 1, wherein the thermoelectric material leg comprises a half-Heusler material.

11. The method of claim 1, wherein at least two thermoelectric material legs are bonded to a header using a direct bonding process to provide a unicouple.

12. The method of claim 1, wherein the adhesion strength between the thermoelectric material leg and the header or electrical connector is greater than about 35 MPa.

13. The method of claim 1, wherein the contact resistance between the thermoelectric material leg and the header or electrical connector is less than 15 μΩ-cm².

14. The method of claim 1, wherein the direct bonding process is performed at a temperature between about 450-1000° C.

15. The method of claim 1, wherein the header or electrical connector is a metal material.

16. The method of claim 15, wherein the metal material comprises at least one of silver, copper, nickel, a nickel-iron alloy, stainless steel, aluminum and titanium.

17. The method of claim 4, wherein the brazing comprises positioning a brazing material at or proximate to an interface between the thermoelectric material leg and the header or electrical connector, and melting the brazing material to cause the brazing material to flow into the interface via alloying or capillary action to bond the thermoelectric material leg to the header or electrical connector.

18. The method of claim 17, wherein the brazing material comprises at least one of silver, copper, a silver-copper based alloy, an aluminum alloy, a nickel alloy and a titanium alloy.

19. The method of claim 5, wherein the solid state diffusion comprises holding the thermoelectric material leg and the header or electrical connector under load at an elevated temperature less than a melting temperature of either the leg or the header or connector for a period sufficient to bond the thermoelectric material leg to the header or electrical connector via interdiffusion of at least one constituent material of the leg or the header or electrical connector.

20. The method of claim 19, wherein the at least one constituent material comprises at least one of silver, copper, a silver-copper based alloy, an aluminum alloy, a nickel alloy and a titanium alloy.

21. The method of claim 5, wherein the solid state diffusion comprises holding the thermoelectric material leg, the header or electrical connector, and a solid interface material located between the leg and the header or electrical connector under load at an elevated temperature less than a melting temperature of the leg, the solid interface material or the header or connector for a period sufficient to bond the thermoelectric material leg, the solid interface material and the header or electrical connector via interdiffusion of at least one constituent material of the leg, the solid interface material or the header or electrical connector.

22. A thermoelectric device produced by a method according to claim 1.

23. A thermoelectric device comprising:
a unicouple comprising an electrically conductive header and a p-type thermoelectric material leg and an n-type thermoelectric material leg with a direct bond at an interface between the thermoelectric material of each leg and the header.

24. The thermoelectric device of claim 23, wherein the direct bond comprises a braze at the interface.

25. The thermoelectric device of claim 23, wherein the direct bond comprises an interdiffusion of header and thermoelectric materials.

26. The thermoelectric device of claim 23, wherein the direct bond comprises an interdiffusion of header and thermoelectric materials with a solid interface material located between each leg and the header.

27. The thermoelectric device of claim 23, wherein the unicouple does not include a metal contact layer between the thermoelectric legs and the header.

28. The thermoelectric device of claim 23, wherein at least one of the p-type thermoelectric material leg and the n-type thermoelectric material leg comprises a half-Heusler material.

29. The thermoelectric device of claim 23, wherein an adhesion strength between at least one of the p-type thermoelectric material leg and the n-type thermoelectric material leg and the header is greater than about 35 MPa.

30. The thermoelectric device of claim 23, wherein a contact resistance between at least one of the p-type thermoelectric material leg and the n-type thermoelectric material leg and the header is less than 15 μΩ-cm².

31. The thermoelectric device of claim 23, wherein the header is a metal material.

32. The thermoelectric material of claim 31, wherein the metal material comprises at least one of silver, copper, nickel, a nickel-iron alloy, stainless steel, aluminum and titanium.

33. The thermoelectric device of claim 24, wherein the braze comprises at least one of silver, copper, a silver-copper based alloy, an aluminum alloy, a nickel alloy and a titanium alloy.
